(19) United States
(12) Patent Application Publication
(10) Pub. No.: US 2025/0194245 A1
(43) Pub. Date: Jun. 12, 2025

(54) DISPLAY PANEL AND DISPLAY DEVICE

(71) Applicant: TCL CHINA STAR OPTOELECTRONICS TECHNOLOGY CO., LTD., Shenzhen (CN)

(72) Inventors: Caifeng WEI, Shenzhen (CN); Chunfang QIU, Shenzhen (CN); Di WU, Shenzhen (CN); Jinlin LIU, Shenzhen (CN)

(73) Assignee: TCL CHINA STAR OPTOELECTRONICS TECHNOLOGY CO., LTD., Shenzhen (CN)

(21) Appl. No.: 18/977,993

(22) Filed: Dec. 12, 2024

(30) Foreign Application Priority Data
Dec. 12, 2023 (CN) 202311702956.1

(51) Int. Cl. H10D 86/40; H10D 86/60

(52) U.S. Cl. CPC H10D 86/441; H10D 86/60

(57) ABSTRACT

The present application discloses a display panel and a display device, wherein the display panel includes a display area and a fanout trace area located on a side of the display area and further includes: a first trace layer including multiple first traces disposed in the fanout trace area and spaced apart; and a second trace layer disposed on a side of the first trace layer and insulated from the first trace layer, the second trace layer including multiple second traces disposed in the fanout trace area and spaced apart. The embodiments of the present application can reduce the parasitic capacitance between the first and second traces, reduce the delay of the signal transmission, and improve the display performance of the display panel.

### CROSS-REFERENCE TO RELATED APPLICATION

This application claims priority to and the benefit of Chinese Patent Application No. 202311702956.1, filed on Dec. 12, 2023, the disclosure of which is incorporated herein by reference in its entirety.

### TECHNICAL FIELD

The present application relates to the field of display technology, particularly to a display panel and a display device.

### BACKGROUND

Currently, display panels usually use an integrated IC, where traces for a source fanout and traces for a gate fanout enter the display panel from a same side. However, due to limitations of IC pins and requirements to alignments among the signal lines in the display panel, the traces for the source fanout and the traces for the gate fanout will inevitably intersect over a large area, resulting in a large positive capacitance and increasing the parasitic capacitance of the entire fanout area, which leads to severe signal delay in the scanning lines and data lines and further affects the display performance of the display panel.

### SUMMARY

The embodiments of the present application provide a display panel and a display device that can reduce the overlapping area between the first traces and second traces, thereby reducing parasitic capacitance.

An embodiment of the present application provides a display panel, the display panel includes a display area and a fanout trace area located on a side of the display area, and further includes:
a first trace layer including multiple first traces disposed in the fanout trace area and spaced apart, the first traces including first line segments extending along a first direction and second line segments extending along a second direction, wherein the second line segments are attached between the first line segments and signal lines located in the display area, the second direction is the direction in which the fanout trace area points towards the display area, and the first direction intersects with the second direction; and
a second trace layer disposed on a side of the first trace layer and insulated from the first trace layer, the second trace layer including multiple second traces disposed in the fanout trace area and spaced apart;
wherein the first line segment is non-overlapping with the second traces along a thickness direction of the display panel, and the second line segment is partially overlapping with the second traces along the thickness direction of the display panel.

In one embodiment of the present application, the display panel further include a driving component, the first trace is attached between the driving component and the signal lines, and the second trace is attached between the driving component and the signal lines; and
the first trace further includes third line segment attached between the driving component and the first line segment, the extension direction of the third line segment is different from that of the first line segment, and the third line segment is non-overlapping with the second trace along the thickness direction of the display panel.

In one embodiment of the present application, the second trace includes a fourth line segment attached to the driving component, a sixth line segment attached to the signal lines, and a fifth line segment attached between the fourth line segment and the sixth line segment; and
wherein the first line segment is parallel to the fifth line segment, the third line segment is parallel to the fourth line segment, and the second line segment is partially overlapping with the fifth line segment along the thickness direction of the display panel.

In one embodiment of the present application, the third line segment and the fourth line segment extend along the second direction.

In one embodiment of the present application, at least one of the fourth line segments is located between two adjacent third line segments, and at least one of the fifth line segments is located between two adjacent first line segments.

In one embodiment of the present application, attaching points between the first line segments and the third line segments in the multiple first traces, and attaching points between the fourth line segments and the fifth line segments in the multiple second traces are located in a same straight line.

In one embodiment of the present application, the multiple first traces are disposed between the display area and the driving component with an interval, and the multiple first traces include a first trace at an outermost edge, the lengths of the first line segments in the first traces near the first trace at the edge are greater than the lengths of the first line segments in the first traces away from the first trace at the edge, and the lengths of the second line segments in the first traces near the first trace at the edge are greater than the lengths of the second line segments in the first traces away from the first trace at the edge, the lengths of the third line segments in the first traces near the first trace at the edge are smaller than the lengths of the third line segments in the first traces away from the first trace at the edge.

In one embodiment of the present application, the sixth line segment includes a first attaching part attached to the fifth line segments, a second attaching part attached to the signal lines, and a third attaching part attached between the first attaching part and the second attaching part, and the third attaching part includes a zigzag-shaped trace; and

the first attaching part and the second attaching part extend along the second direction, and the second line segment is located between two adjacent third attaching parts.

In one embodiment of the present application, among the multiple first traces, distances between adjacent first line segments are equal, distances between adjacent second line segments are equal, and distances between adjacent third line segments are equal.

In one embodiment of the present application, the signal lines include multiple data lines and multiple scanning lines disposed within the display area, and multiple first traces are attached to multiple scanning lines correspondingly, and multiple second traces are attached to multiple data lines correspondingly.

In one embodiment of the present application, the multiple scanning lines include multiple first scanning lines extending along the second direction and disposed along a third direction, and multiple second scanning lines extending along the third direction and disposed along the second direction, the third direction intersects with the second direction, and the multiple first traces are correspondingly attached to the multiple first scanning lines.

In one embodiment of the present application, a display device including a display panel mentioned above.

### Beneficial Effect

The display panel according to the embodiments of the present application reduces the overlap area between the first traces and the second traces by setting the first line segments extending diagonally in the first traces to not overlap with the second traces, thereby reducing the overlap area between the first traces and the second traces, reducing the parasitic capacitance between the first and second traces, reducing signal transmission delay, and enhancing the display performance of the display panel.

### BRIEF DESCRIPTION OF THE DRAWINGS

Through a detailed description of the specific embodiments of the present application in conjunction with the accompanying Figures, the technical solution and other beneficial effects of the present application will become apparent.

FIG. 1 shows a schematic diagram of a fanout trace distribution for a display panel provided by the prior art;

FIG. 2 is an enlarged partial structural diagram at point a in FIG. 1 provided by the prior art;

FIG. 3 is an enlarged partial structural diagram at point b in FIG. 1 provided by the prior art;

FIG. 4 is an enlarged partial structural diagram at point c in FIG. 1 provided by the prior art;

FIG. 5 is a schematic diagram of a planar distribution of a display panel provided in an embodiment of the present application;

FIG. 6 is an enlarged partial structural diagram at point A in FIG. 5 provided by an embodiment of the present application;

FIG. 7 is a schematic diagram of the distribution of the first trace at point A in FIG. provided by an embodiment of the present application;

FIG. 8 is an enlarged partial structural diagram at point B in FIG. 5 provided by an embodiment of the present application;

FIG. 9 is a distribution structure diagram of the first and second traces provided in an embodiment of the present application; and

FIG. 10 is an enlarged partial structural diagram at point C in FIG. 5 provided by an embodiment of the present application.

### DETAILED DESCRIPTION

Below, the technical solutions in the embodiments of the present application will be clearly and completely described in conjunction with accompanying drawings. It is evident that the described embodiments are only some of the embodiments of the present application, but not all. Based on the embodiments of the present application, all other embodiments obtained by those skilled in the field but without inventive step fall within the scope of protection of the present application.

The following disclosure provides many different embodiments or examples for implementing various structures of the application; in order to simplify the disclosure of the present application, the components and arrangements of specific examples are described below. Certainly, they are only examples but not intended to limit the present application. Furthermore, the present application may repeat reference numbers and/or reference signs in different examples for the purpose of simplification and clarity, which does not indicate the relationship between the various embodiments and/or settings discussed. Further, the present application provides various specific examples of processes and materials, but those of ordinary skill in the art may be aware of the application of other processes and/or the use of other materials.

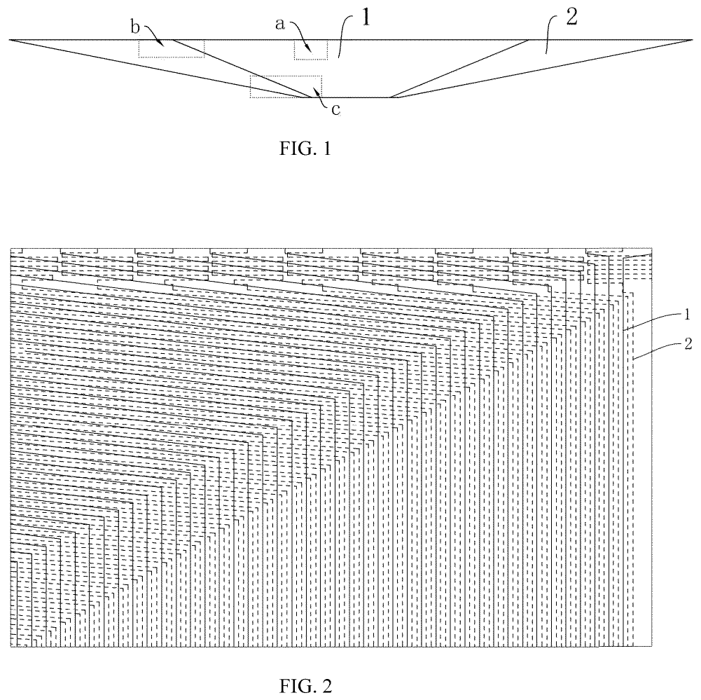

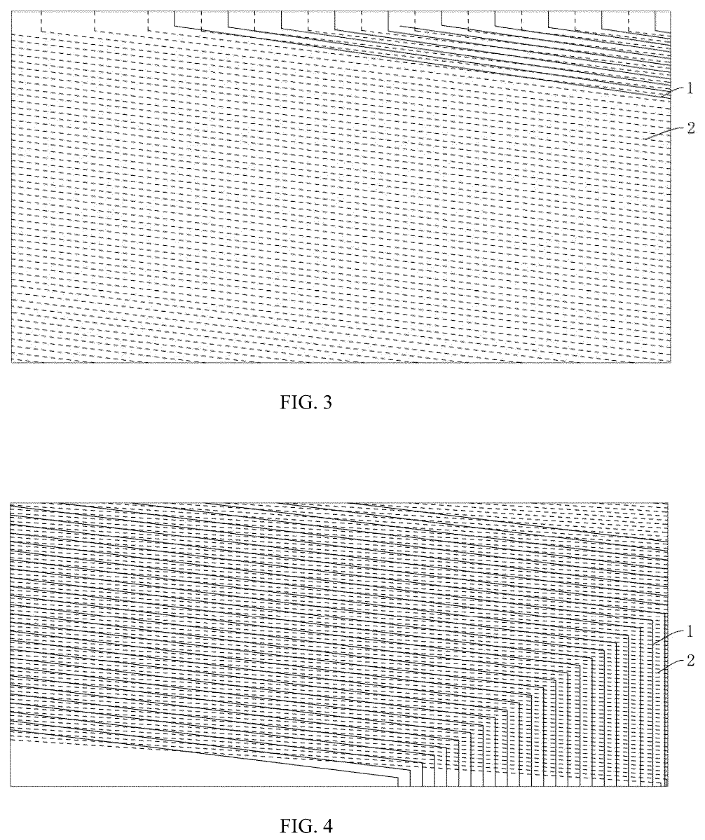

Referring to FIG. 1, FIG. 2, FIG. 3, and FIG. 4, in a display panel with an integrated IC, the display panel is simultaneously equipped with a gate fanout trace 1 and a source fanout trace 2 in one fanout trace area. In order to meet the layout requirement of traces and the respective alignments of gate fanout trace 1 and source fanout trace 2 with the in-plane signal lines, there is a lot of overlap between gate fanout trace 1 and source fanout trace 2. For example, there is a significant horizontal overlap area between diagonal gate fanout trace 1 and source fanout trace 2 along the horizontal direction, causing large positive capacitance and therefore causing the increase of the parasitic capacitance of the entire fanout area of the display, resulting in severe signal delay in gate fanout trace 1 and source fanout trace 2, as well as in the signal lines attached to the plane, further affecting the display performance of the display panel.

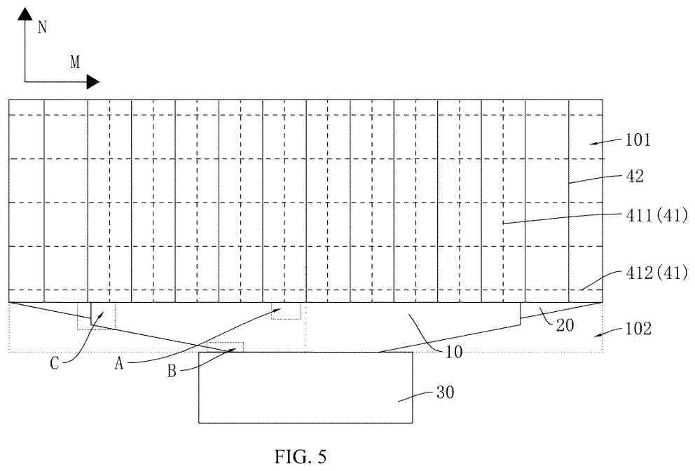

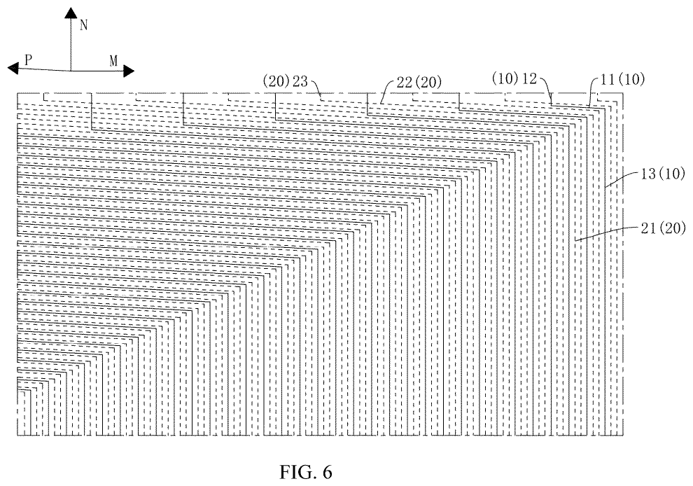

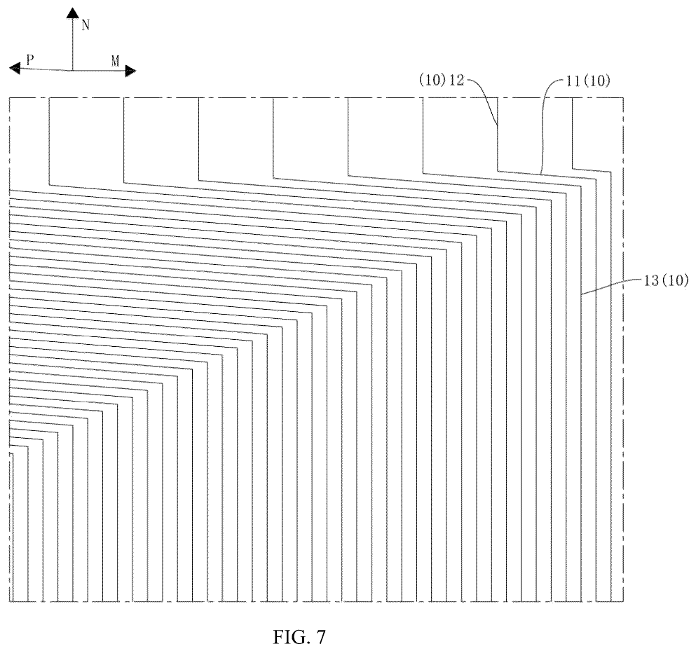

Referring to FIG. 5 and FIG. 6, the embodiment of the present application provides a display panel including a display area 101 and a fanout trace area 102 located on a side of the display area 101.

The display panel further includes a first trace layer and a second trace layer. The first trace layer includes multiple first traces 10 disposed in the fanout trace area 102 and spaced apart. Each of the first trace 10 includes a first line segment 11 extending along a first direction P and a second line segment 12 extending along a second direction N. The second line segment 12 is attached between the first line segment 11 and the signal lines in the display area 101. The second direction N is the direction in which the fanout trace area 102 points towards the display area 101, and the first direction P intersects with the second direction N. The second trace layer is disposed on a side of the first trace layer and insulated from the first trace layer. The first trace layer includes multiple second traces 20 disposed in the fanout trace area 102 and spaced apart.

Among them, the first line segment 11 and the second trace 20 do not overlap along the thickness direction of the display panel, and the second line segment 12 partially overlaps with the second trace 20 along the thickness direction of the display panel.

In the process of implementing the application, the embodiment of the present application disposes the first line segment 11 extending diagonally in the first trace 10 to not overlap with the second trace 20. Compared with the prior art, it can reduce the horizontal overlap area between the first line segment 11 and the second trace 20, thereby reducing the overlap area between the first trace 10 and the second trace 20, that is, reducing the facing area between the first trace 10 and the second trace 20, thereby reducing the parasitic capacitance between the first trace 10 and the second trace 20, reducing the signal transmission delay, and enhancing the display performance of the display panel.

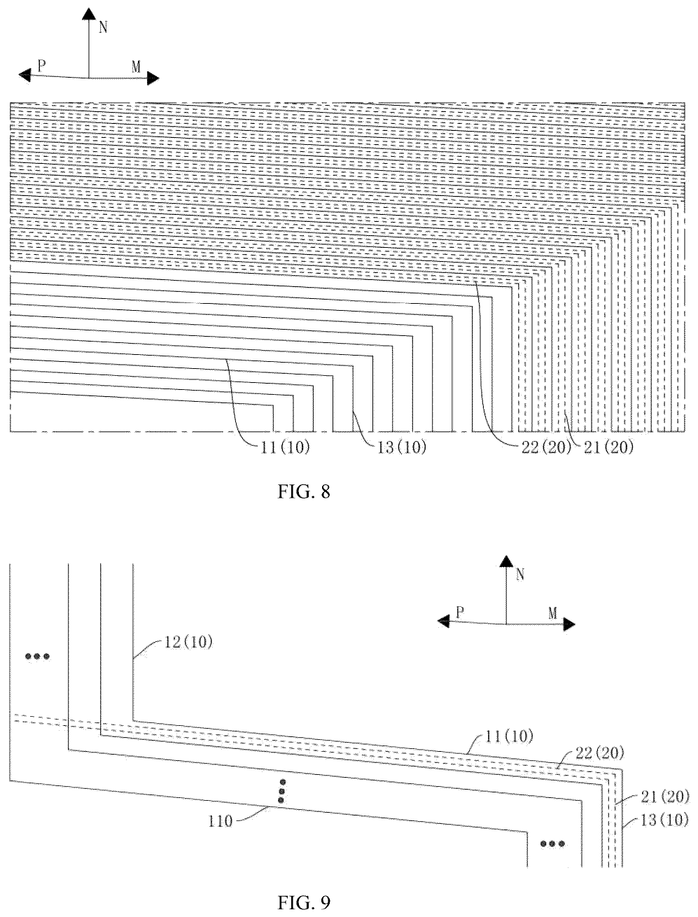

Specifically, referring to FIG. 5, FIG. 6, FIG. 7, FIG. 8, and FIG. 9, the display panel includes a display area 101, a fanout trace area 102 located on a side of the display area 101, and a driving component 30 located on the side of the display area 101 near the fanout trace area 102. It should be noted that the present embodiment does not limit the number of fanout trace areas in the display panel. In the present embodiment, one fanout trace area 102 located on a side of the display area 101 is taken as an example for explanation.

In one embodiment, the driving component 30 is located on a side of the fanout trace area 102 away from the display area 101.

Furthermore, the display panel also includes a first trace layer and a second trace layer arranged at intervals, and at least one insulation layer (not shown in the figure) can be spaced between the first trace layer and the second trace layer. Herein, the first trace layer includes multiple first traces 10 disposed in the fanout trace area 102, and the second trace layer includes multiple second traces 20 disposed in the fanout trace area 102.

Herein, multiple first traces 10 are arranged at intervals in the fanout trace area 102 and attached between the signal lines in the driving component 30 and the display area 101, and multiple second traces 20 are arranged at intervals in the fanout trace area 102 and attached between the signal lines in the driving component 30 and the display area 101. The multiple first traces 10 and the multiple second traces 20 are insulated at intervals.

The first trace 10 includes a third line segment 13 attached to the driving component 30, a second line segment 12 attached to the signal lines within the display area 101, and a first line segment 11 attached between the second line segment 12 and the third line segment 13.

In the embodiment of the present application, the first line segment 11 extends along the first direction P, the second line segment 12 extends along the second direction N, and the first direction P intersects with the second direction N. The second direction N is the direction in which the fanout trace area 102 points towards the display area 101. That means, the first line segment 11 extends diagonally, and the extension direction of the third line segment 13 is different from that of the first line segment 11.

In one embodiment, the third line segment 13 extends along the second direction N. That means, one end of the first trace 10 is attached to the driving component 30, while the other end extends along the forward direction pointing towards the display area 101 first, then extends along a diagonal direction inclined to the forward direction so as to be aligned with the in-plane signal line, and then extends along the forward direction to attach to the signal line inside the display area 101. Since the width of the driving component 30 is smaller than that of the display area 101, the first trace 10 attached to the left side of the driving component 30 in FIG. 5 extends diagonally towards the left side, while the first trace 10 attached to the right side of the driving component 30 in FIG. 5 extends diagonally towards the right side. The first trace 10 attached to the left side of the driving component 30 and the first trace 10 attached to the right side of the driving component 30 can be arranged in an axisymmetric manner.

Similarly, one end of the second trace 20 is attached to the driving component 30, while the other end first extends in the forward direction pointing to the display area 101, then extends in the diagonal direction inclined to the forward direction so as to be aligned with the signal lines inside the display area 101, and then extends in the forward direction to attach to the signal lines inside the display area 101. Since the width of the driving component 30 is smaller than that of the display area 101, the second trace 20 attached to the left side of the driving component 30 in FIG. 5 extends diagonally towards the left side, while the second trace 20 attached to the right side of the driving component 30 in FIG. 5 extends diagonally towards the right side. The second trace 20 attached to the left side of the driving component 30 and the second trace 20 attached to the right side of the driving component 30 in FIG. 5 can be arranged in an axisymmetric manner.

In the embodiment of the present application, the first line segment 11 does not overlap with the second trace 20 along the thickness direction of the display panel, and the second line segment 12 partially overlaps with the second line segment 20 along the thickness direction of the display panel. In the embodiment of the present application, due to the fact that multiple first traces 10 and multiple second traces 20 are located within the fanout trace area 102, and the positions where multiple first traces 10 need to be attached to the display area 101 are different from the positions where multiple second traces 20 need to be attached to the display area 101. It is impossible for multiple first traces 10 and multiple second traces 20 to be disposed in parallel. In order to meet the requirements of disposition and alignment, there will inevitably be overlap between the first traces 10 and the second traces 20. In the prior art shown in FIG. 1, FIG. 2, and FIG. 3, since the lengths of the diagonal gate fanout trace 1 and the diagonal source fanout trace 2, which determine the attaching points between the gate fanout trace 1, the source fanout trace 2, and the display area, are relatively great, there is a significant overlap area in the horizontal direction between the diagonal gate fanout trace 1 and the diagonal source fanout trace 2 in order to facilitate the alignment of gate fanout trace 1 and source fanout trace 2 with the signal lines in the display area in the prior art. However, in the embodiment of the present application, the first trace 10 extends to different positions through an diagonal first line segment 11, so that the first trace 10 can be aligned with signal lines at different positions in the display area 101. In order to solve the problem of large overlap area between the first line segment 11 in the first trace 10 and the fifth line segment 22 in the second trace 20 due to alignment requirements, the embodiment of the present application adds and extends a second line segment 12 in the first trace 10, so that the first line segment 11 does not need to extend to the attaching point of the corresponding signal line, but only needs to extend so far to intersect with a straight line passing through the attaching point and extending along the second direction N. Then, the signal line within the display area 101 will be attached to by extending the second line segment 12 along the second direction N. Therefore, in this embodiment of the present application, the first line segment 11 extending diagonally is disposed to not overlap with the second trace 20, thereby effectively reducing the facing area between the first trace 10 and the second trace 20.

Furthermore, among the multiple first traces 10, the area of the first line segment 11 extending along the first direction P has the largest proportion, which is greater than the area proportion of the second line segment 12 extending along the second direction N, and is also greater than the area proportion of the third line segment 13 extending along the second direction N. Therefore, in this embodiment of the present application, the first line segment 11 does not overlap with the second trace 20, and the overlapping part is located only at the second line segment 12 with a smaller area proportion, which can effectively reduce the facing area and parasitic capacitance between the first trace 10 and the second trace 20. In addition, the second line segment 12 extends along the second direction N instead of diagonally, which can reduce the horizontal overlap area between the second line segment 12 and the second trace 20, effectively reducing the overlap area between the second line segment 12 and the second trace 20, and further reducing the parasitic capacitance between the first trace 10 and the second trace 20.

In addition, the third line segment 13 does not overlap with the second trace 20 along the thickness direction of the display panel, which can further reduce the parasitic capacitance and overlap area between the first trace 10 and the second trace 20.

In the embodiment of the present application, the second trace 20 includes a fourth line segment 21 attached to the driving component 30, a sixth line segment 23 attached to the display area 101, and a fifth line segment 22 attached between the fourth line segment 21 and the sixth line segment 23.

In one embodiment, the first line segment 11 and the fifth line segment 22 are parallel and both extend along the first direction P, while the third line segment 13 and the fourth line segment 21 are parallel and both extend along the second direction N. Herein, at least one fifth line segment 22 is located between two adjacent first line segments 11, and at least one fourth line segment 21 is located between two adjacent third line segments 13. In this embodiment of the present application, every two fifth line segments 22 are located between two adjacent first line segments 11, and every two fourth line segments 21 are located between adjacent two third line segments 13, as an example for explanation.

Herein, based on the parallelism between the first line segment 11 and the fifth line segment 22, as well as the parallelism between the third line segment 13 and the fourth line segment 21, combined with that the attaching points of the first line segment 11 and the third line segment 13 in the multiple first traces 10 and also the attaching points of the fourth line segment 21 and the fifth line segment 22 in the multiple second traces 20 are all located on the same straight line, it is possible to achieve non-overlapping between the first line segment 11 and the second trace 20, and non-overlapping between the third line segment 13 and the second trace 20.

Furthermore, the multiple first traces 10 include a first trace at an outermost edge 110. It can be understood that the multiple first traces 10 are distributed on the left and right sides of the fanout trace area 102, and can further include two first traces at the edges 110 located on leftmost and rightmost sides, respectively. In the illustrated embodiment of the present application, only the first trace at the leftmost edge 110 is shown as an example for explanation.

Herein, the length of the first line segment 11 in the first trace 10 near the first trace at an outermost edge 110 is greater than the length of the first line segment 11 in the first trace 10 away from the first trace at an outermost edge 110, the length of the second line segment 12 in the first trace 10 near the first trace at an outermost edge 110 is greater than the length of the second line segment 12 in the first trace 10 away from the first trace at an outermost edge 110, and the length of the third line segment 13 in the first trace 10 near the first trace at an outermost edge 110 is less than the length of the third line segment 13 in the first trace 10 away from the first trace at an outermost edge 110. It should be noted that the lengths of the first line segment 11, the second line segment 12, and the third line segment 13 in different first traces 10 can be adjusted to make the lengths of the multiple first traces 10 tend to be consistent, in order to reduce the occurrence of signal transmission abnormalities caused by different impedances of different first traces 10.

In one embodiment, among the multiple first traces 10, distances between adjacent first line segments 11 are equal, distances between adjacent second line segments 12 are equal, and distances between adjacent third line segments 13 are equal.

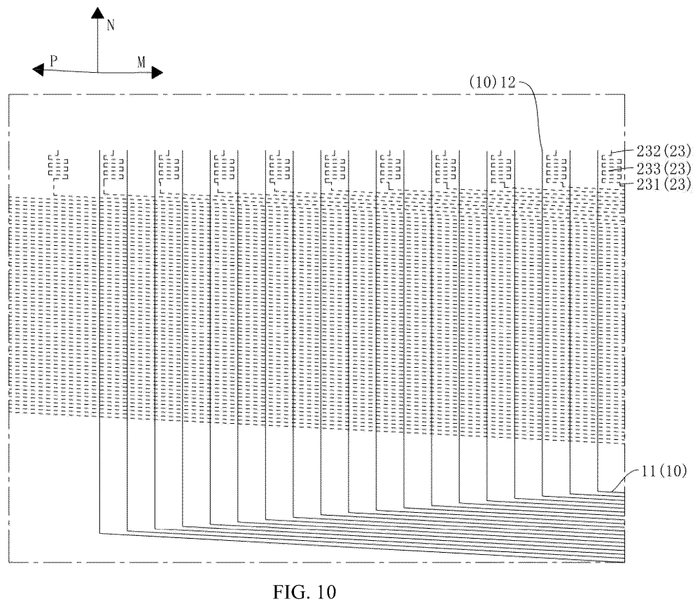

In one embodiment, referring to FIG. 10, the sixth line segment 23 includes a first attaching part 231 attached to the fifth line segment 22, a second attaching part 232 attached to the display area 101, and a third attaching part 233 attached between the first attaching part 231 and the second attaching part 232. The third attaching part 233 includes a zigzag-shaped trace. When the third attaching part 233 has a zigzag-shaped trace, the length differences between different second traces 20 can be flexibly adjusted through the zigzag-shaped trace, so that the lengths of the multiple second traces 20 tend to be consistent, reducing the impedance difference between the multiple second traces 20 and improving the uniformity of signal transmission. Herein, the length of the third attaching part 233 in the second trace 20 on the side near the centerline of the display area 101 is greater than the length of the third attaching part 233 in the second trace 20 on the side far away from the centerline of the display area 101.

In other embodiments of the present application, the third attaching part 233 may also be in form of wavy shape or folded lines, etc.

Herein, the first attaching part 231 and the second attaching part 232 extend along the second direction N, and the second line segment 12 is located between two adjacent third attaching parts 233, even if the second line segment 12 does not overlap with the sixth line segment 23. This can further reduce the overlap area between the first trace 10 and the second trace 20, and reduce the parasitic capacitance between the first trace 10 and the second trace 20.

Please continue to refer to FIG. 5, FIG. 6, FIG. 7, FIG. 8, FIG. 9, and FIG. 10, in the display panel provided by the embodiment of the present application, the signal lines in the display area 101 include multiple scanning lines 41 and multiple data lines 42 disposed in the display area 101, and multiple first traces 10 are correspondingly attached to multiple scanning lines 41, and multiple second traces 20 are correspondingly attached to multiple data lines 42.

In one embodiment, the multiple data lines 42 extend along the second direction N and are disposed along a third direction M, wherein the second direction N intersects with the third direction M. The multiple scanning lines 41 include multiple first scanning lines 411 extending along the second direction N and disposed along the third direction M, as well as multiple second scanning lines 412 extending along the third direction M and disposed along the second direction N.

In one embodiment, the second direction N may be perpendicular to the third direction M.

Herein, multiple first traces 10 are attached in one-to-one correspondence with multiple first scanning lines 411, and multiple second traces 20 are attached in one-to-one correspondence with multiple data lines 42, so that the signals in the driving component 30 can be transmitted to the corresponding scanning lines 41 and data lines 42. In the display panel provided by the embodiment of the present application, the first traces 10 and the second traces 20 can share one driving component 30.

It should be noted that a second scanning line 412 is attached to at least one first scanning line 411, and the signal is transmitted from the driving component 30 to the first trace 10, then transmitted to the first scanning line 411 through the first trace 10, and then transmitted from the first scanning line 411 to the second scanning line 412. The display area 101 of the display panel is equipped with multiple pixel units disposed in an array along the second direction N and the third direction M. These pixel units are disposed in multiple rows and columns, with each data line 42 attached to a column of pixel units and each second scanning line 412 attached to a row of pixel units, to achieve signal output for each pixel unit.

In one embodiment, the first trace 10 can be disposed on the same layer as the first scanning line 411, that is, formed in the same photomask. The second trace 20 can be disposed on the same layer as the data line 42, that is, formed in the same photomask. Thus, the first trace layer further includes the first scanning line 411, and the second trace layer further includes the data line 42.

In other embodiments of the present application, the first trace 10 can be prepared in the same layer as other conductive film layers in the display area 101 of the display panel than the first scanning line 411, and the second trace 20 can be prepared in the same layer as other conductive film layers in the display area 101 of the display panel than the data line 42. The first trace 10 can be attached to the first scanning line 411 through wire-switching-over-hole connection, and the second trace 20 can also be attached to the data line 42 through wire-switching-over-hole connection.

In the embodiment of the present application, since the data line 42 needs to be distributed corresponding to each column of pixel units, the second trace 20 also needs to extend to the edge of the display area 101 to transmit signals to the data line 42 at the edge, while the first scanning line 411 outputs signals to the pixel units through the second scanning line 412. Therefore, the first trace 10 does not need to extend to the edge of the display area 101, and the extension path of the multiple second traces 20 along the third direction M is greater than the extension path of the multiple first traces 10 along the third direction M.

Furthermore, the present embodiment provides an Example of implementing the present application and a Comparative Example to verify the effects of the first trace 10 and the second trace 20 provided by the present embodiment. In the Comparative Example, the trace in the fanout trace area is disposed as shown in FIGS. 1 to 4. In the Example, the trace in the fanout trace area 102 is arranged as shown in FIGS. 5 to 10. The other structures and materials of the display panel in the Example and the Comparative Example are the same, and simulation is carried out using Huada Jiutian RCExplorer to obtain the data shown in Table 1.

TABLE 1
Parasitic capacitance data table

| | Parasitic capacitance | | Reduced by |
|---|---|---|---|
| Comparative Example | 437.856 | fF | 98.48% |
| Example of implementing the | 6.66 | fF | |

present application

It should be noted that the parasitic capacitance test in Table 1 shows the parasitic capacitance between a source fanout trace 2 and a gate fanout trace 1 in the Comparative Example, as well as the parasitic capacitance between a second trace 20 and a first trace 10 in the Example. From the data in Table 1, it can be seen that the parasitic capacitance of the display panel provided by the Example can be significantly reduced, thereby effectively reducing signal delay and improving the display performance of the display panel.

In summary, the embodiments of the present application can reduce the horizontal overlap area between the first line segment 11 and the second trace 20 compared to the prior art by disposing the first line segment 11 extending diagonally in the first trace 10 to not overlap with the second trace 20, which can further reduce the overlap area between the first trace 10 and the second trace 20. That means, the facing area between the first trace 10 and the second trace 20 can be reduced, the parasitic capacitance between the first trace 10 and the second trace 20 can be reduced, the signal transmission delay can be reduced, and the display performance of the display panel can be enhanced.

In addition, the embodiments of the present application also provide a display device comprising the display panel described in the above embodiments.

In one embodiment, the display device may include an electronic paper reader.

It can be understood that the display device provided by the embodiments of the present application has the same display panel as the above embodiments, and therefore, the display device has the same beneficial effects as the display panel in the above embodiments, the description of which therefore will be omitted.

In the above embodiments, the descriptions for each embodiment focus on different aspects respectively. For the parts that are not detailed in one embodiment, please refer to the relevant descriptions of other embodiments.

The display panel and the display device provided in the embodiments of the present application have been introduced in details above. Specific examples are described herein to explain the principles and implementation methods of the present application. The above embodiments are only used to help understand the technical solution and core idea of the present application. Those of ordinary skill in the art should understand that they can still modify the technical solutions recorded in the foregoing embodiments, or make equivalent substitutions for some of the technical features. And these modifications or substitutions do not make the essence of the corresponding technical solutions deviate from the scope of the technical solutions of the embodiments of the present application.

What is claimed is:

1. A display panel, comprising a display area and a fanout trace area located on a side of the display area, and further comprising:
a first trace layer including multiple first traces disposed in the fanout trace area and spaced apart, the first traces including first line segments extending along a first direction and second line segments extending along a second direction, wherein the second line segments are attached between the first line segments and signal lines located in the display area, the second direction is the direction in which the fanout trace area points towards the display area, and the first direction intersects with the second direction; and
a second trace layer disposed on a side of the first trace layer and insulated from the first trace layer, the second trace layer including multiple second traces disposed in the fanout trace area and spaced apart;
wherein the first line segment is non-overlapping with the second traces along a thickness direction of the display panel, and the second line segment is partially overlapping with the second traces along the thickness direction of the display panel.

2. The display panel of claim 1, wherein the display panel further comprises a driving component, the first trace is attached between the driving component and the signal lines, and the second trace is attached between the driving component and the signal lines; and
the first trace further comprises third line segments attached between the driving component and the first line segment, the extension direction of the third line segment is different from that of the first line segment, and the third line segment is non-overlapping with the second trace along the thickness direction of the display panel.

3. The display panel of claim 2, wherein the second trace comprises fourth line segments attached to the driving component, sixth line segments attached to the signal lines, and fifth line segments attached between the fourth line segments and the sixth line segments; and
wherein the first line segment is parallel to the fifth line segment, the third line segment is parallel to the fourth line segment, and the second line segment is partially overlapping with the fifth line segment along the thickness direction of the display panel.

4. The display panel of claim 3, wherein the third line segment and the fourth line segment extend along the second direction.

5. The display panel of claim 3, wherein at least one of the fourth line segments is located between two adjacent third line segments, and at least one of the fifth line segments is located between two adjacent first line segments.

6. The display panel of claim 3, wherein attaching points between the first line segments and the third line segments in the multiple first traces, and attaching points between the fourth line segments and the fifth line segments in the multiple second traces are located in a same straight line.

7. The display panel of claim 3, wherein the multiple first traces are disposed between the display area and the driving component with an interval, and the multiple first traces comprise a first trace at an outermost edge, the lengths of the first line segments in the first traces near the first trace at the edge are greater than the lengths of the first line segments in the first traces away from the first trace at the edge, and the lengths of the second line segments in the first traces near the first trace at the edge are greater than the lengths of the second line segments in the first traces away from the first trace at the edge, and the lengths of the third line segments in the first traces near the first trace at the edge are smaller than the lengths of the third line segments in the first traces away from the first trace at the edge.

8. The display panel of claim 3, wherein the sixth line segment comprises a first attaching part attached to the fifth line segments, a second attaching part attached to the signal lines, and a third attaching part attached between the first attaching part and the second attaching part, and the third attaching part comprises a zigzag-shaped trace; and
wherein the first attaching part and the second attaching part extend along the second direction, and the second line segment is located between two adjacent third attaching parts.

9. The display panel of claim 3, wherein among the multiple first traces, distances between adjacent first line segments are equal, distances between adjacent second line segments are equal and, distances between adjacent third line segments are equal.

10. The display panel of claim 1, wherein the signal lines comprise multiple data lines and multiple scanning lines disposed within the display area, and multiple first traces are attached to multiple scanning lines correspondingly, and multiple second traces are attached to multiple data lines correspondingly.

11. The display panel of claim 10, wherein the multiple scanning lines comprise multiple first scanning lines extending along the second direction and disposed along a third direction, and multiple second scanning lines extending along the third direction and disposed along the second direction, wherein the third direction intersects with the second direction, and the multiple first traces are correspondingly attached to the multiple first scanning lines.

12. A display device comprising a display panel, wherein the display panel omprises a display area and a fanout trace area located on a side of the display area, wherein the display panel further includes:
a first trace layer including multiple first traces disposed in the fanout trace area and spaced apart, the first trace including first line segments extending along a first direction and second line segments extending along a second direction, wherein the second line segments are attached between the first line segment and signal lines located in the display area, the second direction is the direction in which the fanout trace area points towards the display area, and the first direction intersecting with the second direction; and
a second trace layer disposed on a side of the first trace layer and insulated from the first trace layer, the second trace layer including multiple second traces disposed in the fanout trace area and spaced apart;
wherein the first line segment is non-overlapping with the second traces along a thickness direction of the display panel, and the second line segment is partially overlapping with the second traces along the thickness direction of the display panel.

13. The display device of claim 12, wherein the display panel further includes a driving component, the first trace is attached between the driving component and the signal lines, and the second trace is attached between the driving component and the signal lines; and
the first trace further comprises third line segments attached between the driving component and the first line segment, the extension direction of the third line segment is different from that of the first line segment, and the third line segment is non-overlapping with the second trace along the thickness direction of the display panel.

14. The display device of claim 13, wherein the second trace comprises fourth line segments attached to the driving component, sixth line segments attached to the signal lines, and fifth line segments attached between the fourth line segments and the sixth line segments; and
the first line segment is parallel to the fifth line segment, the third line segment is parallel to the fourth line segment, and the second line segment is partially overlapping with the fifth line segment along the thickness direction of the display panel.

15. The display device of claim 14, wherein the third line segment and the fourth line segment extend along the second direction.

16. The display device of claim 14, wherein at least one of the fourth line segments is located between two adjacent third line segments, and at least one of the fifth line segments is located between two adjacent first line segments.

17. The display device of claim 14, wherein attaching points between the first line segments and the third line segments in the multiple first traces, and attaching points between the fourth line segments and the fifth line segments in the multiple second traces, are located in a same straight line.

18. The display device of claim 14, wherein the multiple first traces are disposed between the display area and the driving component with an interval, and the multiple first traces include a first trace at an outermost edge, the lengths of the first line segments in the first traces near the first trace at the edge are greater than the lengths of the first line segments in the first traces away from the first trace at the edge, and the lengths of the second line segments in the first traces near the first trace at the edge are greater than the lengths of the second line segments in the first traces away from the first trace at the edge, the lengths of the third line segments in the first traces near the first trace at the edge are smaller than the lengths of the third line segments in the first traces away from the first trace at the edge.

19. The display device of claim 14, wherein the sixth line segment includes a first attaching part attached to the fifth line segments, a second attaching part attached to the signal lines, and a third attaching part attached between the first attaching part and the second attaching part, and the third attaching part includes a zigzag-shaped trace; and
the first attaching part and the second attaching part extend along the second direction, and the second line segment is located between two adjacent third attaching parts.

20. The display device of claim 14, wherein among the multiple first traces, distances between adjacent first line segments are equal, distances between adjacent second line segments are equal, and distances between adjacent third line segments are equal.
